(19) United States
(12) Patent Application Publication
(10) Pub. No.: US 2026/0314286 A1
(43) Pub. Date: Oct. 8, 2026

(54) COMPOSITION FOR WET ETCHING AND MANUFACTURING METHOD OF SEMICONDUCTOR DEVICE USING THE COMPOSITION

(71) Applicant: Samsung Electronics Co., Ltd., Suwon-si (KR)

(72) Inventors: Dai Hyun KIM, Suwon-si (KR); Jae Sung LEE, Suwon-si (KR); Mihyun PARK, Suwon-si (KR); Sang Won BAE, Suwon-si (KR)

(73) Assignees: Samsung Electronics Co., Ltd., Suwon-si (KR); Soulbrain Co., Ltd., Seongnam-si (KR)

(21) Appl. No.: 19/413,240

(22) Filed: Dec. 9, 2025

(30) Foreign Application Priority Data
Apr. 8, 2025 (KR) 10-2025-0045667

(51) Int. Cl. H10P 50/68; C09K 13/08; H10D 84/01; H10P 70/00

(52) U.S. Cl. CPC H10P 50/683; C09K 13/08; H10D 84/0158; H10P 70/23

(57) ABSTRACT

A composition for wet etching may include HF, a corrosion inhibitor, and an aprotic organic solvent having a dielectric constant of less than or equal to 60, The corrosion inhibitor may be a polycyclic fused ring compound in which a heterocyclic ring containing one or more S atoms therein is fused to an additional ring.

### CROSS-REFERENCE TO RELATED APPLICATION

This application claims priority to and the benefit of Korean Patent Application No. 10-2025-0045667 filed with the Korean Intellectual Property Office on Apr. 8, 2025, the entire contents of which are incorporated herein by reference.

### BACKGROUND

### 1. Field

This disclosure relates to a composition for wet etching, and a method of manufacturing a semiconductor device using the same.

### 2. Description of the Related Art

As semiconductor products become increasingly miniaturized, in a manufacturing process of the semiconductor products, there is an increasing demand for performing a process of removing unnecessary metal contents on a substrate with high efficiency and high precision.

A semiconductor device may be manufactured, for example, by disposing a laminate of a metal layer as a wiring material, an etching stop film, and an insulation film on a substrate and then, forming a resist film on this laminate to perform a photolithography process and a dry etching process.

In the photolithography process, a method of etching or removing foreign substances attached to the surface of the substrate by using a treatment solution that dissolves the metal contents is widely known.

For example, in the photolithography process, there is a method of etching the metal layer and/or the insulation film on the substrate through dry etching by using the resist film as a mask. Herein, residues derived from the metal layer and/or the insulation film, etc. may often be attached to the substrate, the metal layer, and/or the insulation film. In order to remove these attached residues, washing with the treatment solution may be often performed.

In addition, the resist film used as a mask during the etching is removed from the laminate by a dry method (dry ashing) or a wet method. However, when the dry ashing method is used to remove the resist from the laminate, there may be cases that residues derived from the resist film, etc. remain attached onto the laminate. In order to remove the attached residues, washing with the treatment solution may be often performed.

As described above, the treatment solution, in the process of manufacturing a semiconductor device, is used to remove the metal contents (etching residues and ashing residues) on the substrate and/or the resist film, etc.

### SUMMARY

One aspect of the present disclosure provides a composition for wet etching for removing residue after dry etching on a high-k dielectric film including a layer including a high-k material and an oxide thereof.

Another aspect of the present disclosure is to provide a method for manufacturing a semiconductor device using a composition for wet etching.

According to an example embodiment, a composition for wet etching according may include HF; a corrosion inhibitor; and an aprotic organic solvent having a dielectric constant of less than or equal to 60.

The corrosion inhibitor may be a polycyclic fused ring compound in which a heterocyclic ring containing one or more S atoms therein may be fused to an additional ring.

A method for manufacturing a semiconductor device according to an embodiment may include providing a semiconductor substrate including a structure that may be exposed, the structure including a high-k dielectric residue on a lower layer, the high-k dielectric residue including hafnium oxide, the lower layer containing at least one of a metal atom and a non-metal atom, and cleaning the semiconductor substrate including the structure with the composition for wet etching.

The composition for wet etching according to one aspect may have improved removal ability for hafnium oxide remaining after dry etching and may have low corrosiveness to a material included in a lower layer, where the lower layer may be laminated adjacent to a high-k dielectric film including hafnium oxide on a substrate. The composition for wet etching may enable higher etching selectivity to be realized. Therefore, productivity and reliability may be greatly improved and the cleaning performance may be improved for processes related to forming microcircuits of semiconductor devices.

### BRIEF DESCRIPTION OF THE DRAWINGS

FIGS. 1 and 2 are schematic views illustrating a process for removing hafnium oxide residue remaining after dry etching.

FIG. 3 is a TEM image showing a cross-section of a semiconductor device after wet etching.

### DETAILED DESCRIPTION

The present disclosure will be described more fully hereinafter with reference to the accompanying drawings, in which embodiments of inventive concepts are shown. The present disclosure may be modified in various different ways, all without departing from the spirit or scope of the present disclosure.

In the drawings, parts having no relationship with the description are omitted for clarity of the embodiments, and the same or similar constituent elements are indicated by the same reference numerals throughout the specification.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. In addition, in the drawings, for convenience of description, thicknesses of a part and an area are exaggeratedly illustrated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As used herein, when a definition is not otherwise provided, ‘substituted’ refers to replacement of hydrogen of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 aryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, when a definition is not otherwise provided, “hetero” refers to one including 1 to 10 heteroatoms selected from N, O, S, and P.

As used herein, the term acrylic polymer refers collectively to an acrylic polymer and a methacrylic polymer.

As used herein, when a definition is not otherwise provided, “alkyl group” refers to a linear or branched aliphatic hydrocarbon group. The alkyl group may be “saturated alkyl group” without any double bond or triple bond.

The alkyl group may be a C1 to C20 alkyl group. For example, the alkyl group may be a C1C1 to C10 alkyl group or a C1 to C6 alkyl group. For example, the C1 to C5 alkyl group means that the alkyl chain contains 1 to 5 carbon atoms and is selected from methyl, ethyl, propyl, iso-propyl, n-butyl, iso-butyl, sec-butyl, and t-butyl.

The alkyl group may refer to a methyl group, an ethyl group, a propyl group, an isopropyl group, a butyl group, an isobutyl group, a t-butyl group, a pentyl group, a hexyl group, and the like.

As used herein, when a definition is not otherwise provided, “cycloalkyl group” means a monovalent cyclic aliphatic hydrocarbon group.

The above cycloalkyl group refers to a cyclopropyl group, a cyclobutyl group, a cyclopentyl group, a cyclohexyl group, and the like.

As used herein, when a definition is not otherwise provided, “alkenyl group” refers to an aliphatic unsaturated alkenyl group including at least one double bond as a linear or branched aliphatic hydrocarbon group.

As used herein, when a definition is not otherwise provided, “alkynyl group” refers to an aliphatic unsaturated alkynyl group including at least one triple bond as a linear or branched aliphatic hydrocarbon group.

As used herein, “aryl group” refers to a substituent in which all atoms in the cyclic substituent have a p-orbital and these p-orbitals are conjugated and may include a monocyclic or fused ring polycyclic functional group (i.e., rings sharing adjacent pairs of carbon atoms) functional group.

More specifically, the substituted or unsubstituted C6 to C30 aryl group may refer to a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, or a combination thereof, but is not limited thereto.

A composition for wet etching according to an embodiment is described below.

The composition for wet etching according to the present disclosure removes high-k (HfOₓ) residues generated in a dry etch cut process by wet etching, thereby limiting and/or minimizing loss of process-exposed film materials (TiAlN, TiAlC, SiO₂, etc.) in addition to the high-k (HfOₓ) residues, thereby increasing the etching selectivity of high-k (HfOₓ) versus other process-exposed film materials.

### HF

HF (hydrogen fluoride) may be used in an amount of about 0.1 to about 5 wt %, specifically about 0.2 to about 5 wt %, and more specifically about 0.2 to about 3 wt %, based on 100 wt % of the total composition for wet etching.

### Corrosion Inhibitor

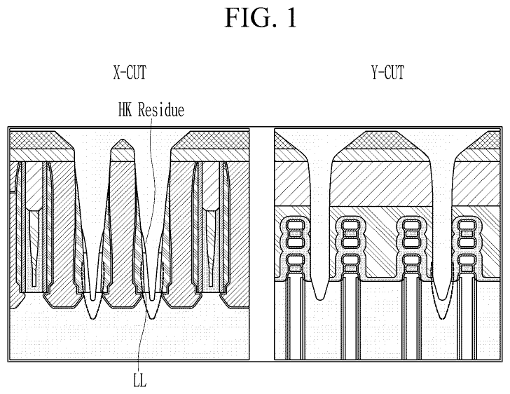

The aforementioned HF is very effective in dissolving the etch byproducts (—HfOₓ—F, HfF₄) after etching HfO₂ (a in FIG. 1), but at the same time, it also attacks TiAlC, TiAlN, and SiO₂ as shown in FIG. 1, generating etch byproducts such as AlF₃ and TiF₆.

FIG. 1: Etching mechanism in HF aqueous solution

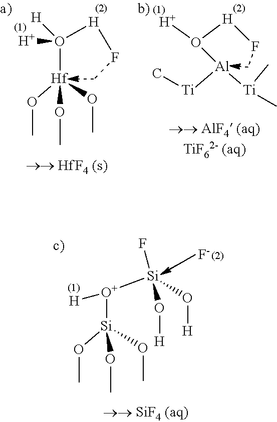

The corrosion inhibitor included in the composition for wet etching according to an embodiment can limit and/or suppress additional etching by HF forming a coordination bond with the S atom included in the ring of the corrosion inhibitor to a film material exposed in the process, such as TiAlN or TiAlC.

A corrosion inhibitor according to an embodiment may be a polycyclic fused ring compound in which a heterocyclic ring containing one or more S atoms within the ring is fused to an additional ring.

For example, the additional ring may be at least one of a carbocyclic ring and a heterocyclic ring (also referred to as a heterocyclic compound).

For example, the polycyclic fused ring compound may be a compound in which two to five rings are fused, specifically a compound in which two to four rings are fused, and most specifically a compound in which two rings are fused.

For example, each ring of the polycyclic fused ring compound may be a 5-membered or 6-membered carbocyclic ring or heterocyclic ring.

For example, the 5-membered or 6-membered carbocyclic ring may be an aromatic ring.

For example, the 5-membered or 6-membered carbocyclic ring may be a heteroaromatic ring.

For example, the polycyclic fused ring compound may further include a N atom.

For example, the N atom may be included together in a heterocyclic ring containing S.

For example, the N atom may be included in an additional ring to which a heterocyclic ring containing S is fused.

For example, the N atom may be included in a substituent substituted on a heterocyclic ring containing S.

For example, the corrosion inhibitor may be represented by Chemical Formula 1.

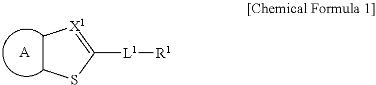

In Chemical Formula 1,
A is a substituted or unsubstituted C6 to C20 aromatic ring,
X¹ is CR² or N,
L¹ is a single bond, carbonyl, or a substituted or unsubstituted C1 to C10 alkylene group, and
R¹ and R² are each independently hydrogen, an amine group, or a substituted or unsubstituted C1 to C10 alkyl group.

For example, in Chemical Formula 1, A may be a substituted or unsubstituted benzene ring, a substituted or unsubstituted naphthalene ring, or a substituted or unsubstituted phenanthrene ring. In some embodiments, in Chemical Formula 1, A may be a substituted or unsubstituted benzene ring or a substituted or unsubstituted naphthalene ring. In some embodiments, in Chemical Formula 1, A may be a substituted or unsubstituted benzene ring.

For example, the corrosion inhibitor may be at least one of benzo[b]thiophene-2-carboxamide and benzothiazole.

The corrosion inhibitor may be used in an amount of about 0.001 to about 1 wt %, specifically about 0.005 to about 1 wt %, about 0.01 to about 1 wt %, and more specifically about 0.01 to about 0.5 wt %, based on 100 wt % of the total composition for wet etching.

### Aprotic Organic Solvent

The etching mechanism of HfO₂, TiAlN, TiAlC, or SiO₂ films in HF aqueous solution is as shown in FIG. 1 above.

That is, HfO₂, which is an HK material, is (1) protonated and (2) then bonds are broken by the F source, generating HfF₄ as an etch byproduct, which has low solubility (10⁻⁶-10⁻⁸ M) in aqueous solution.

In the case of TiAlN or TiAlC, similar to the etching of HK, 1) after protonation, 2) the bond is broken by the SN₂ reaction by the F source, but etch byproducts such as AlF₄⁻ and TiF₆⁻ are generated and AlF₄⁻ and TiF₆⁻ have high solubility in aqueous solutions.

The etch byproducts such as AlF₄⁻ and TiF₆⁻ have low solubility in organic solvents, so that their removal may be limited and/or suppressed, thereby limiting and/or preventing corrosion.

Considering these etching mechanisms and etch byproducts, it is important to limit and/or minimize the water content so as to exclude the solvent environment, e.g., the aqueous solution environment, which increases the solubility of the HK etch byproduct while limiting and/or suppressing the dissolution of the TiAlC and SiO₂ etch byproducts.

An aprotic organic solvent according to an embodiment may include less than about 1 wt % of water.

The aprotic organic solvent according to an embodiment may have aspects such as no hydrogen bond donor properties and electron lone pairs that can very weakly act as hydrogen bond acceptors. The aprotic organic solvent may have a dielectric constant of less than or equal to about 60, for example, less than or equal to about 50, more specifically, about 5 to about 70, or greater than or equal to about 10 and less than or equal to about 50.

Additionally, a dipole moment of the aprotic organic solvent may be greater than or equal to about 2, for example, greater than or equal to about 3, greater than or equal to about 4, greater than or equal to about 5, or less than or equal to about 6.

After high-K (HK, HfO₂) etching, the aforementioned aprotic organic solvent is expected to induce dissolution of etch byproducts by surrounding and stabilizing the etch byproducts, while limiting and/or suppressing the dissolution of etch byproducts for TiAlC, etc., and thus, it is expected that the etching selectivity can be increased.

As a non-limiting example, the aprotic organic solvent may be at least one selected from acetonitrile, dimethyl sulfoxide, dimethylformamide, tetrahydrofuran, sulfolane, butyl acetate, gamma-butyrolactone, propylene glycol methyl ether, and propylene glycol methyl ether acetate.

### Other Additives

The composition for wet etching according to the present disclosure may optionally include additives such as a surfactant and an antifoaming agent.

The surfactant may be a cationic, anionic, nonionic, or amphoteric surfactant.

Examples of the antifoaming agent include a polysiloxane antifoaming agent (e.g.: polydimethylsiloxane), a polyethylene glycol methyl ether polymer, an ethylene oxide/propylene oxide copolymer, and a glycol ether capped acetylene diol ethoxylate.

In some embodiments, the etching composition of the present disclosure may particularly exclude at least one component but include at least one additive is included in any combination. For example, oxygen scavengers, quaternary ammonium salts including quaternary ammonium hydroxides, amines, alkali bases (e.g., NaOH, KOH, and LiOH), antifoaming agents, other surfactants differing from the antifoaming agents, other fluoride-containing compounds differing from HF, abrasives, hydroxycarboxylic acids, carboxylic acids lacking amino groups, and polycarboxylic acids, buffers, and non-azole corrosion inhibitors may be included.

The composition of the present disclosure may be prepared by simply mixing these components or blending two compositions.

The wet etching composition described in the present disclosure may be used to remove residues after dry etching under the presence of a high-k dielectric film including an HK material, particularly, under the presence of a high-k dielectric film including HfO₂. In addition, this composition may be used for the high-k dielectric film including HfO₂ in a process for manufacturing a semiconductor device, which includes a step of selectively removing the residues after the dry-etching from the surface of the microelectronic device.

In another embodiment of the present disclosure, provided is a method of manufacturing a semiconductor device, which includes a step of washing the semiconductor substrate.

The method may be performed, for example, by contacting the semiconductor substrate including the residues after the dry etching with the cleaning composition of the present disclosure.

According to an embodiment, the method of manufacturing the semiconductor device may include providing a semiconductor substrate including a structure in which a high-k dielectric film including hafnium oxide and a lower layer containing at least one of a metal atom and a non-metal atom other than hafnium are laminated, and cleaning the substrate, in which at least one of the high-k dielectric film and the lower layer is exposed, with a composition for wet etching according to claim 1.

A semiconductor substrate including a structure in which a high-k dielectric film including hafnium oxide and a lower layer including at least one metal atom and non-metal atom other than hafnium are laminated may be provided after at least one dry etching process among an ion implantation process, an etching process, or an ashing process.

The hafnium oxide remaining after the dry etching may be selectively removed by a composition for wet etching.

At this time, selectivity of a removal rate of the hafnium oxide: a removal rate of the lower layer may be greater than or equal to about 3:1, and for example, the selectivity of the removal rate of the hafnium oxide: the removal rate of the lower layer may be greater than or equal to about 4:1.

The lower layer may include at least one of a metal film and an insulating film, and
the metal film may include one selected from TiN, TiAlN, TiAlC, and an alloy thereof.

The insulating film may include one selected from silicon, silicon oxide, silicon nitride, silicon oxynitride, silicon oxycarbonitride, SOD (spin on dielectric), silicate, a metal oxide including Al₂O₃, TiO₂, ZrO₂, La₂O₃, TaO₅, MgO, BaO, SrO, or (Ba,Sr)TiO₃, and a combination thereof.

The cleaning with the composition for wet etching may be performed by contacting the substrate, in which at least one of the high-k dielectric film and the lower layer is exposed, with the composition for wet etching for about 30 to about 300 seconds at a temperature of about 10 to about 25° C.

Hereinafter, the present disclosure will be described in more detail through examples of preparing the aforementioned composition for wet etching. However, the technical features of the present disclosure are not limited by the following Examples.

### Evaluation 1: Evaluation of Etching Selectivity

The results of checking the etching ability of etching compositions according to Example 1, Example 2, and Comparative Examples 1 to 12 are shown in Tables 1 to 3. The etching compositions of Example 1, Example 2, and Comparative Examples to 1 to 12 were used to check the HK E/R, TiAlC E/R, SiOCN E/R, and HK/TiAlC. Results were selectivity were measured by using VSEM, TEM, and the like.

TABLE 1

| | | | | |
|---|---|---|---|---|
| | | Comp. | Comp. | Comp. |
| Ex. 1 | Ex. 2 | Ex. 1 | Ex. 2 | Ex. 3 |

| Composition | HF (wt%) | | 0.25 | | |
|---|---|---|---|---|---|
| | Organic | Type | Sulfolane | Sulfolane | Sulfolane |
| | solvent | (wt %) | (99.45) | (98.75) | (99.45) |

| | |
|---|---|
| Dielectric | 43.4 |
| constant | |
| Dipole | 5.65 |
| moment | |

| | | | | | |
|---|---|---|---|---|---|
| Corrosion inhibitor | A1 | A2 | B1 | B2 | B3 |
| (wt %) | (0.3) | (1.0) | (0.3) | (0.3) | (0.3) |

| | | | | | |
|---|---|---|---|---|---|
| HK E/R (Å/min) | 14.4 | 4.3 | 12.1 | 0 | 11.4 |
| TiAIC E/R (Å/min) | 3.3 | 1.3 | 12.4 | 3.4 | 12.5 |
| SiOCN E/R (Å/min) | 0 | 0 | 0 | 0 | 0 |
| HK/TiAIC etching selectivity | 4.36 | 3.31 | 0.98 | 0 | 0.91 |

TABLE 2

| | | | | |
|---|---|---|---|---|
| Comp. | Comp. | Comp. | Comp. | Comp. |
| Ex. 4 | Ex. 5 | Ex. 6 | Ex. 7 | Ex. 8 |

| Composition | HF (wt %) | | 0.25 | | | |
|---|---|---|---|---|---|---|
| | Organic | Type | Sulfolane | AA | PC | Sulfolane |
| | solvent | (wt %) | (99.45) | (99.45) | (99.45) | (99.45) |
| | | Dielectric | 43.4 | 6.2 | 64 | 43.4 |
| | | constant | | | | |
| | | Dipole | 5.65 | 1.74 | 4.9 | 5.65 |
| | | moment | | | | |

| | | | | | |
|---|---|---|---|---|---|
| Corrosion inhibitor | B4 | B5 | A1 | B6 | B7 |
| (wt %) | (0.3) | (0.3) | (0.3) | (0.3) | (0.3) |

| | | | | | |
|---|---|---|---|---|---|
| HK E/R (Å/min) | 5.5 | 9 | 5.1 | 8.5 | 1.4 |
| TiAIC E/R (Å/min) | 5.4 | 34.1 | 25.6 | 19.2 | 5.1 |
| SiOCN E/R (Å/min) | 0 | 2.3 | 0 | 0 | 0 |
| HK/TiAIC etching selectivity | 1.02 | 0.26 | 0.20 | 0.44 | 0.27 |

*AA: Acetic Acid
*PC: Propylene Carbonate

TABLE 3

| | | | |
|---|---|---|---|
| Comp. | Comp. | Comp. | Comp. |
| Ex. 9 | Ex. 10 | Ex. 11 | Ex. 12 |

| Composition | HF (wt %) | | 0.25 | |
|---|---|---|---|---|
| | Organic | Type | Sulfolane | Sulfolane |
| | solvent | (wt %) | (99.45) | (98.75) |

| | |
|---|---|
| Dielectric | 43.4 |
| constant | |
| Dipole | 5.65 |
| moment | |

| | | | | |
|---|---|---|---|---|
| Corrosion inhibitor | B8 | B9 | B10 | B11 |
| (wt %) | (0.3) | (0.3) | (0.3) | (1.0) |

| | | | | |
|---|---|---|---|---|
| HK E/R (Å/min) | 1.1 | 3.2 | 7.2 | 6.3 |
| TiAIC E/R (Å/min) | 6.8 | 8.9 | 12.1 | 3.1 |
| SiOCN E/R (Å/min) | 0 | 0 | 0 | 0 |
| HK/TiAIC etching selectivity | 0.16 | 0.36 | 0.60 | 2.03 |

A1: Benzo[b]thiophene-2-carboxamide
A2: Benzothiazole
B1: Triazole
B2: Methylsulfide
B3: Terazole
B4: 2,2-Bithiophene
B5: Thiophene-3-thiocarboxamide
B6: Methionine
B7: Dimethylsulfide
B8: Benzotriazole
B9: Tolyltriazole
B10: 2-Aminothiazole
B11: Thiazole

Referring to Tables 1 to 3, in the compositions including a corrosion inhibitor within the example range and additionally including a substituted sulfolane solvent, HK E/R was not only maintained at a desired (and/or alternatively predetermined) level or higher, but also etching of SiN and TiAlC were limited and/or suppressed. On the contrary, in the compositions including the corrosion inhibitor within the comparative example range, it was confirmed that a SiN film was not removed, or the etch rate (E/R) of HK and TiAlC was reduced. This is because the solvent lowered the solubility of TiAlC, thereby reducing the removal ability by HF. In addition, TiAlC was still removed at a high ratio, resulting in low etching selectivity.

In other words, in the examples, hafnium oxide (HK) residues were selectively removed, but corrosion of a lower layer adjacent thereto was limited. In Comparative Examples 1 to 12, the lower layer adjacent to a high-k dielectric film was simultaneously corroded, exhibiting low removal rate selectivity.

### Evaluation 2: CT Process Evaluation

A CT process was performed by cutting Gate PC existing in a vertical direction (x-axis) in a horizontal direction (y-axis), and in the Gate PC, various Gate metals such as High-k (HfOx), TiAlN, TiN, and TiAlC were filled for the evaluation. After the CT process, the compositions of Table 2 were used for a wet etching process to remove HK residues on the side wall, and the results are shown in FIGS. 1 to 3.

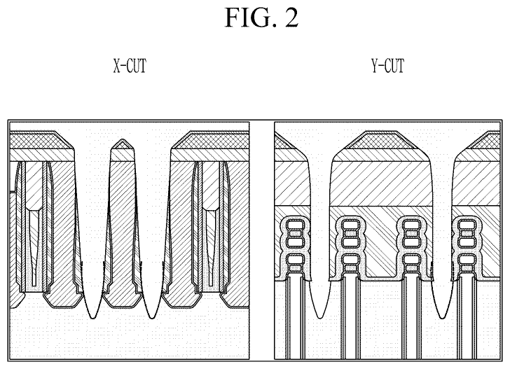

FIGS. 1 and 2 are schematic views illustrating the process for removing hafnium oxide residues remaining after the dry etching.

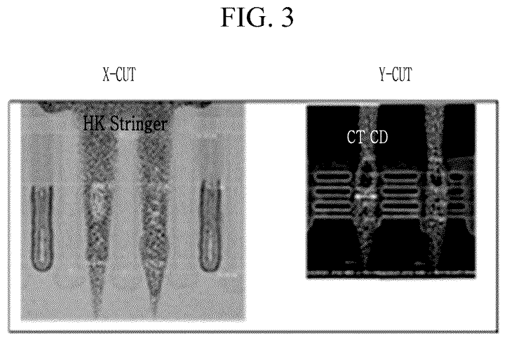

FIG. 3 is a TEM image showing a cross-section of a semiconductor device after the wet etching.

Referring to FIG. 1, the hafnium oxide remaining before the wet etching after the dry etching was produced on the sidewall of the etched surface. The hafnium oxide remaining before the wet etching is labeled as HK residue and is on a lower layer LL.

Referring to FIGS. 2 and 3, after the wet etching, the lower layer LL adjacent to the high-k dielectric film was not only limited and/or suppressed from etching, but also the hafnium oxide residues HK Residue were removed.

According to an example embodiment, a method of preparing a composition for wet etching may include mixing HF, a corrosion inhibitor, and an aprotic organic solvent together. The aprotic organic solvent may have a dielectric constant of less than or equal to 60. The corrosion inhibitor may be a polycyclic fused ring compound in which a heterocyclic ring containing one or more S atoms therein may be fused to an additional ring. The additional ring may be at least one of a carbocyclic ring and a heterocyclic compound.

The corrosion inhibitor may be represented by Chemical Formula 1:

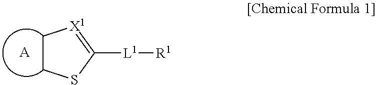

In Chemical Formula 1, A may be a substituted or unsubstituted C6 to C20 aromatic ring and X¹ may be CR² or N. Also, L¹ may be a single bond, a carbonyl, or a substituted or unsubstituted C1 to C10 alkylene group. Also, R¹ and R² each independently may be hydrogen, an amine group, or a substituted or unsubstituted C1 to C10 alkyl group.

The corrosion inhibitor may be at least one of benzo[b]thiophene-2-carboxamide and benzothiazole.

The polycyclic fused ring compound may be a compound in which two to five rings are fused. Each ring of the polycyclic fused ring compound may be a 5-membered or 6-membered carbocyclic ring or heterocyclic ring. The polycyclic fused ring compound may further include an N atom.

The aprotic organic solvent may include less than about 1 wt % of water. The aprotic organic solvent may include at least one selected from acetonitrile, dimethyl sulfoxide, dimethylformamide, tetrahydrofuran, sulfolane, butyl acetate, gammabutyrolactone, propylene glycol methyl ether, and propylene glycol methyl ether acetate. The HF may be included in an amount of about 0.1 to 5 wt % based on 100 wt % of a total of the composition for wet etching. The corrosion inhibitor may be included in an amount of 0.001 to 1 wt % based on 100 wt % of a total of the composition for wet etching.

While inventive concepts have been particularly shown and described with reference to presented embodiments thereof, it is to be understood that inventive concepts are not limited to the presented embodiments, but, on the contrary, are intended to cover various modifications and equivalent arrangements included within the spirit and scope of the appended claims.

What is claimed is:

1. A composition for wet etching, comprising HF;
a corrosion inhibitor; and
an aprotic organic solvent having a dielectric constant of less than or equal to 60,
wherein the corrosion inhibitor is a polycyclic fused ring compound in which a heterocyclic ring containing one or more S atoms is fused to an additional ring.

2. The composition for wet etching of claim 1, wherein
the additional ring is at least one of a carbocyclic ring and a heterocyclic compound.

3. The composition for wet etching of claim 1, wherein
the polycyclic fused ring compound is a compound in which two to five rings are fused.

4. The composition for wet etching of claim 1, wherein
each ring of the polycyclic fused ring compound is a 5-membered or 6-membered carbocyclic ring or heterocyclic ring.

5. The composition for wet etching of claim 1, wherein
the polycyclic fused ring compound further comprises an N atom.

6. The composition for wet etching of claim 1, wherein
the corrosion inhibitor is represented by Chemical Formula 1: 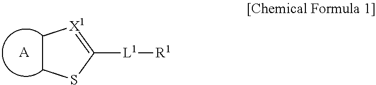
wherein, in Chemical Formula 1,
A is a substituted or unsubstituted C6 to C20 aromatic ring,
X¹ is CR² or N,
L¹ is a single bond, a carbonyl, or a substituted or unsubstituted C1 to C10 alkylene group, and
R¹ and R² are each independently hydrogen, an amine group, or a substituted or unsubstituted C1 to C10 alkyl group.

7. The composition for wet etching of claim 1, wherein
the corrosion inhibitor is at least one of benzo[b]thiophene-2-carboxamide and benzothiazole.

8. The composition for wet etching of claim 1, wherein
a dipole moment (D) of the aprotic organic solvent is greater than or equal to about 2.

9. The composition for wet etching of claim 1, wherein
the aprotic organic solvent comprises less than about 1 wt % of water.

10. The composition for wet etching of claim 1, wherein
the aprotic organic solvent is at least one selected from acetonitrile, dimethyl sulfoxide, dimethylformamide, tetrahydrofuran, sulfolane, butyl acetate, gammabutyrolactone, propylene glycol methyl ether, and propylene glycol methyl ether acetate.

11. The composition for wet etching of claim 1, wherein
the HF is included in an amount of about 0.1 to 5 wt % based on 100 wt % of a total of the composition for wet etching.

12. The composition for wet etching of claim 1, wherein
the corrosion inhibitor is included in an amount of 0.001 to 1 wt % based on 100 wt % of a total of the composition for wet etching.

13. A method of manufacturing a semiconductor device, comprising
providing a semiconductor substrate including a structure that is exposed,
the structure including a high-k dielectric residue on a lower layer,
the high-k dielectric residue including hafnium oxide,
the lower layer containing at least one of a metal atom and a non-metal atom, and
cleaning the semiconductor substrate including the structure with the composition for wet etching according to claim 1.

14. The method of claim 13, wherein the providing the semiconductor substrate including the structure that is exposed includes:
forming a high-k dielectric film on a lower layer on the semiconductor substrate; and
performing at least one process among an ion implantation process, an etching process, or an ashing process on the high-k dielectric film, wherein
a remaining portion of the high-k dielectric film after the performing at least one process corresponds to the high-k dielectric residue in the structure of the semiconductor substrate including the structure.

15. The method of claim 14, wherein
the cleaning the semiconductor substrate including the structure with the composition for wet etching includes selectively removing the hafnium oxide in the high-k dielectric residue.

16. The method of claim 15, wherein
a selectivity of a removal rate of the hafnium oxide to a removal rate of the lower layer is greater than or equal to 3:1.

17. The method of claim 13, wherein
the lower layer comprises at least one of a metal film and an insulating film.

18. The method of claim 17, wherein
the metal film comprises at least one of TiN, TiAlN, TiAlC, and an alloy thereof.

19. The method of claim 17, wherein
the insulating film comprises one of from silicon, silicon oxide, silicon nitride, silicon oxynitride, silicon oxycarbonitride, spin on dielectric, silicate, a metal oxide, or a combination thereof, and
the metal oxide includes at least one of Al₂O₃, TiO₂, ZrO₂, La₂O₃, TaO₅, MgO, BaO, SrO, or (Ba,Sr)TiO₃, or a combination thereof.

20. The method of claim 13, wherein
the cleaning the semiconductor substrate including the structure with the composition for wet etching is performed by contacting the semiconductor substrate including the structure with the composition for wet etching for 30 to 300 seconds at a temperature of 10 to 25° C.
